(19) United States
(12) Patent Application Publication
(10) Pub. No.: US 2002/0175719 A1
(43) Pub. Date: Nov. 28, 2002

(54) Transistor drive circuits and methods using selective discharge of terminal capacitance

(76) Inventor: Isaac Cohen, Dix Hills, NY (US)

Correspondence Address: MYERS BIGEL SIBLEY & SAJOVEC, PO BOX 37428, RALEIGH, NC, 27627, US

(21) Appl. No.: 09/942,394

(22) Filed: Aug. 29, 2001

Related U.S. Application Data
(60) Provisional application No. 60/286,734, filed on Apr. 25, 2001.

(51) Int. Cl. H03B 1/00; H03K 3/00

(52) U.S. Cl. 327/108

(57) ABSTRACT

A drive circuit for driving a transistor includes a unidirectional current conducting circuit, e.g., a diode, coupled between a first node and a capacitance coupled to a controlling electrode of the transistor. The drive circuit further includes a discharge circuit, e.g., a transistor, coupled to a second node and operative to provide a discharge path from the capacitance. An isolation circuit, e.g., a transformer, may be coupled to the unidirectional current conducting circuit and to the discharge circuit at the first and second nodes, respectively. In some embodiments, a complementary drive circuit is provided. Operating methods and power conversion apparatus are also discussed.

### RELATED APPLICATION

This application claims the benefit of the U.S. Provisional Application Serial No. 60/286,734, entitled “Transistor Drive Circuits and Methods Using Selective Discharge of Terminal Capacitance,” to Cohen, filed Apr. 25, 2001 (Attorney Docket No. 9202-4PR), which is hereby incorporated by reference as if set forth herein in its entirety.

### BACKGROUND OF THE INVENTION

The invention relates to transistor circuits and operating methods thereof, and more particularly, to transistor drive circuits and methods.

Switch mode power converters, such as resonant converters, quasi-resonant converters, and actively clamped single ended converters, often use power transistors connected in a “totem pole” (series) configuration and operated in a complementary fashion. Such transistor circuits are often driven by signals that have wide ranging duty cycles and or frequency. Commonly, the control of these complementary transistors includes introducing a small amount of dead time, i.e., time during which neither transistor conducts, between changes in the states of the complementary transistors. In addition, it may be desirable to drive one of the transistors, the “high side” transistor, using an isolated drive circuit.

Conventionally, pulse transformers and/or solid-state level shifter circuits are used to drive such high side transistors. Pulse transformers may provide effective galvanic isolation, high dielectric strength and desirable “dV/dt” immunity. However, they often do not operate correctly in response to input signals that have widely ranging duty cycles, e.g., from near 0% to near 100%, or widely ranging frequencies. Solid-state drivers, such as the L6380 by SGS Thomson, may be able to use such input signals, but may have limited dielectric strength and relatively high susceptibility to dV/dt induced malfunctions.

### SUMMARY OF THE INVENTION

According to embodiments of the invention, a drive circuit for driving a transistor is provided. The drive circuit includes a unidirectional current conducting circuit coupled between a first node and a capacitance coupled to a controlling electrode of the transistor, the unidirectional current conducting circuit operative to charge the capacitance responsive to a voltage at the first node. The drive circuit further includes a discharge circuit coupled to a second node and operative to provide a discharge path from the capacitance responsive to a voltage at the second node. The unidirectional current conducting circuit may include a diode coupled between the first node and the capacitance. The discharge circuit may include a second transistor including a controlling electrode coupled to the second node and a controlled electrode coupled to the capacitance. The capacitance may comprise a capacitance directly connected to the controlling electrode of the transistor, e.g., an inherent capacitance at the controlling electrode, or may comprise a capacitance indirectly coupled to the controlling electrode of the transistor by an intermediate circuit, such as a driver.

In other embodiments of the invention, an isolation circuit may be coupled to the unidirectional current conducting circuit and to the discharge circuit at the first and second nodes, respectively. The isolation circuit may include a first winding magnetically coupled to respective ones of second and third windings. The second winding may be coupled to the unidirectional current conducting circuit at the first node, and the third winding may be coupled to the discharge circuit at the second node.

According to other embodiments of the invention, a complementary drive circuit for driving first and second transistors includes a first winding magnetically coupled to respective ones of a second, third, fourth and fifth windings. The complementary drive circuit further includes a first diode coupled between the second winding and a first capacitance coupled to a controlling electrode of the first transistor, a third transistor having a controlling electrode coupled to the third winding and a controlled electrode coupled to the controlling electrode of the first transistor, a second diode coupled between the fourth winding and a second capacitance coupled to a controlling electrode of a second transistor, and a fourth transistor having a controlling electrode coupled to the fifth winding and a controlled electrode coupled to the controlling electrode of the second transistor. For example, the complementary drive circuit may include first and second transformers, wherein the first winding comprises primary windings of the first and second transformers, the second and third windings comprises first and second secondary windings of the first transformer, and the fourth and fifth windings comprise first and second secondary windings of the second transformer.

In still other embodiments of the invention, a power conversion apparatus includes a transistor. The power conversion apparatus further includes a transistor drive circuit including a unidirectional current conducting circuit coupled between a first node and a capacitance coupled to a controlling electrode of the transistor, the unidirectional current conducting circuit operative to charge the capacitance responsive to a voltage at the first node, and a discharge circuit coupled to a second node and operative to provide a discharge path from the capacitance responsive to a voltage at the second node.

In method embodiments of the invention, a transistor is driven by unidirectionally conducting current from a first node to a capacitance coupled to a controlling electrode of the transistor responsive to a voltage at the first node to thereby induce a charge on the capacitance and transition the transistor to a first state. The charge on the capacitance is then maintained notwithstanding the voltage at the first node to thereby maintain the transistor in the first state. A discharge path from the capacitance is then opened responsive to a voltage at a second node to thereby transition the transistor to a second state.

Transistor drive circuits and methods according to embodiments of the invention can provide several advantages over conventional transistor drive circuits. Transistor drive circuits and methods according to the invention can provide excellent galvanic isolation and, therefore, desirable “dV/dt” immunity, while providing the capability to operate using input signals that have widely ranging duty cycles and/or frequencies. In addition, transistor drive circuits and methods according to embodiments of the invention can provide “break before make” action without undue circuit complexity.

### BRIEF DESCRIPTION OF THE DRAWINGS

FIG. 1 is a schematic diagram illustrating a transistor drive circuit according to embodiments of the invention.

FIG. 2 is a schematic diagram illustrating an isolated transistor drive circuit according to other embodiments of the invention.

FIG. 3 is a waveform diagram illustrating exemplary operations of the isolated drive circuit of FIG. 2 according to embodiments of the invention.

FIG. 4 is a schematic diagram illustrating a complementary transistor drive circuit according to embodiments of the invention.

FIG. 5 is a schematic diagram illustrating a power conversion apparatus according to embodiments of the invention.

FIG. 6 is a schematic diagram illustrating transistor drive circuit according to other embodiments of the invention.

### DETAILED DESCRIPTION

The invention now will be described more fully with reference to the accompanying drawings, in which specific embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, like numbers refer to like elements. It will be appreciated that the invention is applicable to complementary circuit arrangements to those described herein.

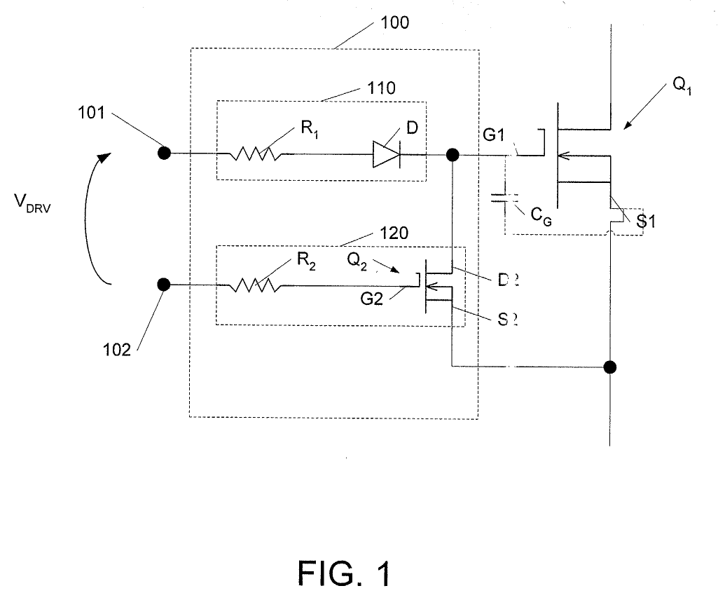

FIG. 1 illustrates a transistor drive circuit 100 for driving a transistor Q₁, here shown as a field effect transistor. The transistor Qi may be, for example, a power transistor used in a power supply or power converter, such as a power transistor used in an active rectifier or inverter circuit. The driver circuit 100 drives the transistor Qi responsive to a voltage V_{DRV} applied to first and second nodes 101, 102 of the drive circuit 100. As shown, the drive transistor Q₁ has a capacitance C_{G} at a controlling electrode (e.g., gate) G1 thereof. The transistor drive circuit 100 includes a unidirectional current conducting circuit 110, here shown as including a resistor R₁ and a diode D connected in series between the first node 101 and the controlling electrode G1 of the transistor Q₁. The transistor drive circuit 100 also includes a discharge circuit 120, here shown as including a transistor Q₂ having a first controlled electrode (e.g., source/drain) D2 coupled to the controlling electrode G1 of the driven transistor Qi and a controlling electrode (e.g., gate) G2 coupled to the second node 102 via a resistor R₂. A second controlled electrode S2 of the second transistor Q2 is coupled to a controlled electrode S1 of the first transistor Q1.

The unidirectional current conducting circuit 110 is operative to charge the capacitance C_{G} responsive to the voltage V_{DRV}, in particular, when the voltage at the first node 101 is sufficiently positive with respect to the voltage at the controlling electrode G1 of the transformer Q₁to forward bias the diode D. The discharge circuit 120 is operative to alternately prevent and allow discharge of the capacitance C_{G} responsive to the voltage at the second node 102, in particular, when the voltage at the second node 102 is sufficiently positive to turn on the transistor Q₂.

It will be appreciated that, according to other embodiments of the invention, the unidirectional current conducting circuit 110 and the discharge circuit 120 may be implemented in other ways that those illustrated in FIG. 1. For example, the diode D may be replaced with other types of circuitry that performs unidirectional current conduction, such as a switching circuit employing a transistor(s) or other switching device(s). Similarly, the transistor Q2 may be replaced with another type of device operative to provide discharge path control. The resistors R₁, R₂ may be discrete resistors, resistances provided by other devices and/or resistance inherent to structures such as wiring or device terminals. The capacitance C_{G} may comprise a capacitance integrally associated with the driven transistor Q₁, e.g., the gate-to-source capacitance inherent in a field effect transistor. It will be appreciated, however, that the capacitance C_{G} may include a separate capacitance, e.g., a discrete capacitor. It will be further appreciated that, although FIG. 1 illustrates a single driven transistor Q₁, the invention may also be used to multiple, parallel-driven transistors.

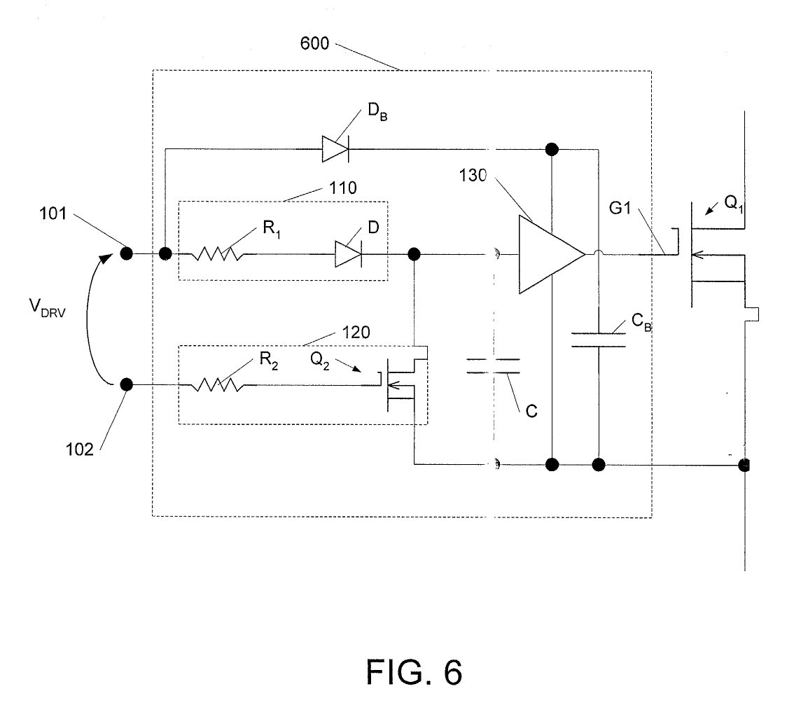

Although FIG. 1 illustrates the transistor controlling capacitance C_{G} connected directly to the transistor Q₁, in other embodiments of the invention, such a capacitance may be coupled to the driven transistor via intermediate circuitry, as in the transistor drive circuit 600 illustrated in FIG. 6. Like components of the drive circuit 600 and the drive circuit 100 of FIG. 1 are indicated by like reference numerals, and description of such components of the drive circuit 600 will not be repeated in light of the preceding description of these components with reference to FIG. 1.

The drive circuit 600 of FIG. 6 differs from the drive circuit 100 of FIG. 1 in that, among other things, instead of charging and discharging a capacitance C_{G} connected directly to the controlling electrode (gate) G1 of the transistor Q₁, the drive circuit 600 includes a capacitance C that is coupled to the controlling electrode G1 of the transistor Q₁ via a driver 130. The charging and discharging of the capacitance C may be controlled by the unidirectional current conducting circuit 110 and the discharge circuit 120 in the same manner in which the capacitance C_{G} of FIG. 1 is controlled. The use of the intermediate driver 130 may be advantageous, for example, where the driver 130 provides additional power handling capability needed to drive the transistor Q₁. The driver 130 may include, but is not limited to, any of a number of different conventional drivers, the operations of which are known to those skilled in the art and will not be discussed in further detail.

The driver circuit 600 also differs from the drive circuit 100 in that it also includes a bias circuit, here shown as including a diode D_{B} and capacitance C_{B}, that is coupled to the driver 130 and the first node 101. Assuming that the capacitance C_{B} is of sufficient size, the bias circuit may bias (power up) the driver 130 responsive to a positive voltage at the first node 101, and maintain the bias on the driver at least until the discharge circuit 120 acts to discharge the capacitance C. It will be appreciated that although FIG. 6 illustrates use of such a bias circuit, the driver 130 may be powered in other ways, e.g., from an independent power supply.

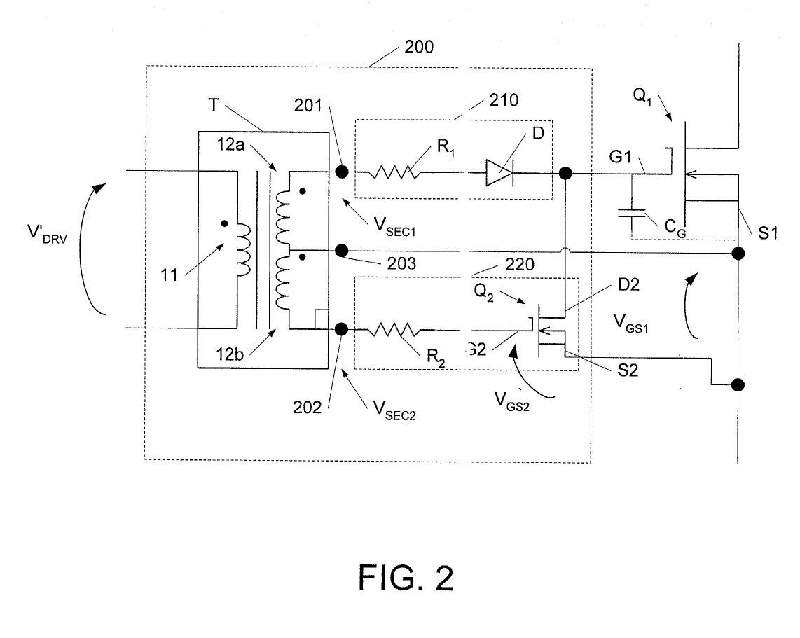

FIG. 2 illustrates a transistor drive circuit 200 according to other embodiments of the invention, in particular, a drive circuit similar to that of FIG. 1, but with an isolation capability. The drive circuit 200 includes an isolation circuit, here shown as including a transformer T including a primary winding 11. The transformer T also includes first and second secondary windings 12a, 12b that are coupled to a unidirectional current conducting circuit 210 and a discharge circuit 220 at respective first and second nodes 201, 202. The unidirectional current conducting circuit 210 includes a diode D and a transistor R₁ coupled in series between the first secondary winding 12a and a controlling electrode (e.g., gate) G1 of a transistor Q₁ to be driven. The discharge circuit 220 includes a transistor Q₂ having its controlling electrode (e.g., gate) G2 coupled to the second secondary winding 12b via a resistor R₂. The transistor Q₂ has a first controlled electrode D2 (e.g., source/drain) coupled to the controlling electrode G1 of the driven transistor Q₁, and a second controlled electrode (e.g., source/drain) S2 coupled to a controlled electrode S1 (e.g., source/drain) of the driven transistor Q₁. The unidirectional current conducting circuit 210 and the discharge circuit 220 are operative to charge and discharge, respectively, a capacitance C_{G} at the controlling electrode G1 of the driven transistor Q1 responsive to a voltage V′_{DRV} applied to the primary winding 11 of the transformer T.

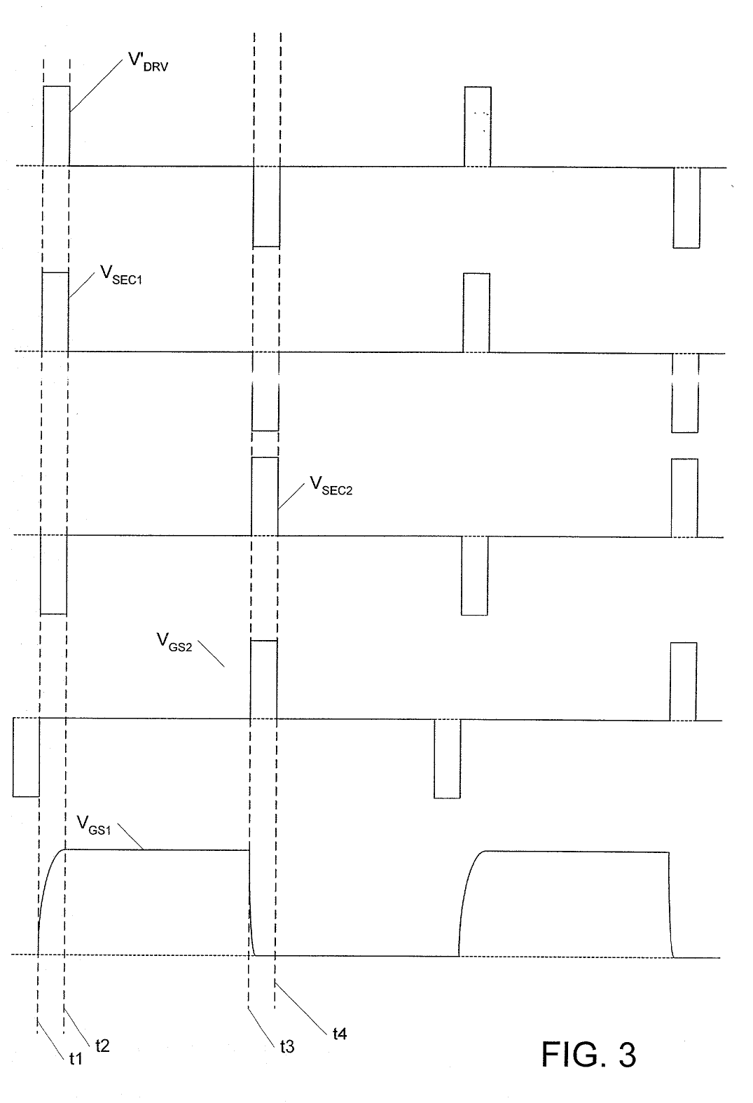

Exemplary operations of the transistor drive circuit 200 will now be described with reference to FIG. 3. A positive pulse in the input voltage V′_{DRV} at a time to drives a voltage V_{SEC1} at the first node 201 to a positive voltage with respect to a common voltage at a node 203 where the first and second secondary windings 12a, 12b are coupled to a controlled electrode (e.g., source/drain) S1 of a driven transistor Q₁. The positive pulse in the input voltage V′_{DRV} simultaneously drives a voltage V_{SEC2} negative. The positive voltage at the first node 201 forward biases the diode D, causing current to flow into the capacitance C_{G} from the first secondary winding 12a, which, in turn, produces a positive gate-source voltage V_{GS1} to be developed at the controlling electrode G1 of the transistor Q₁. The rise time for the gate-to-source voltage V_{GS1} is dependent upon the resistance R₁ and the capacitance C_{G}.

At a time t2, the input voltage V′_{DRV} is brought to zero, thus causing the voltages V_{SEC1}, V_{SEC2} at the first and second nodes to fall towards zero. Through the current blocking action of the diode D, however, the gate to source voltage V_{GS1} remains positive, causing the driven transistor Q₁ to remain in a conducting state. At a subsequent time t3, a negative input voltage V′_{DRV} is applied across the primary winding 11. This drives the voltage V_{SEC1} at the first node 201 negative and the voltage V_{SEC1} at the second node 202 positive. This produces a positive gate to source voltage V_{GS2} on the transistor Q₂, causing it to conduct and, thus, allow the capacitance C_{G} to discharge. This drives the gate to source voltage V_{GS1} towards zero volts, transitioning the driven transistor Q₁ to a non-conducting state. At a subsequent time t4, the input voltage V′_{DRV} is again brought to zero, thus causing the voltages V_{SEC1}, V_{SEC2} at the first and second nodes to again fall towards zero. The capacitance C_{G} remains discharged until the input voltage V′_{DRV} again goes positive.

For the embodiments illustrated, because the coupling resistance provided by the transistor Q₂ can be made relatively low, the “turn off” time for the driven transistor Q₁ may be made less than its “turn on” time. This characteristic can be beneficial in complementary drive applications. In particular, because the turn on time provided by the drive circuit 200 can be made longer than the turn off time, “break before make” action can be achieved, thus reducing the likelihood of short circuited operation, i.e., operation in which both of the series connected transistors are “on.” The resistor R2 may be selected such that prevents ringing between the leakage of the transformer T and the capacitance of the transistor Q₂ without introducing unacceptable delay in the turn off of the driven transistor Q₁.

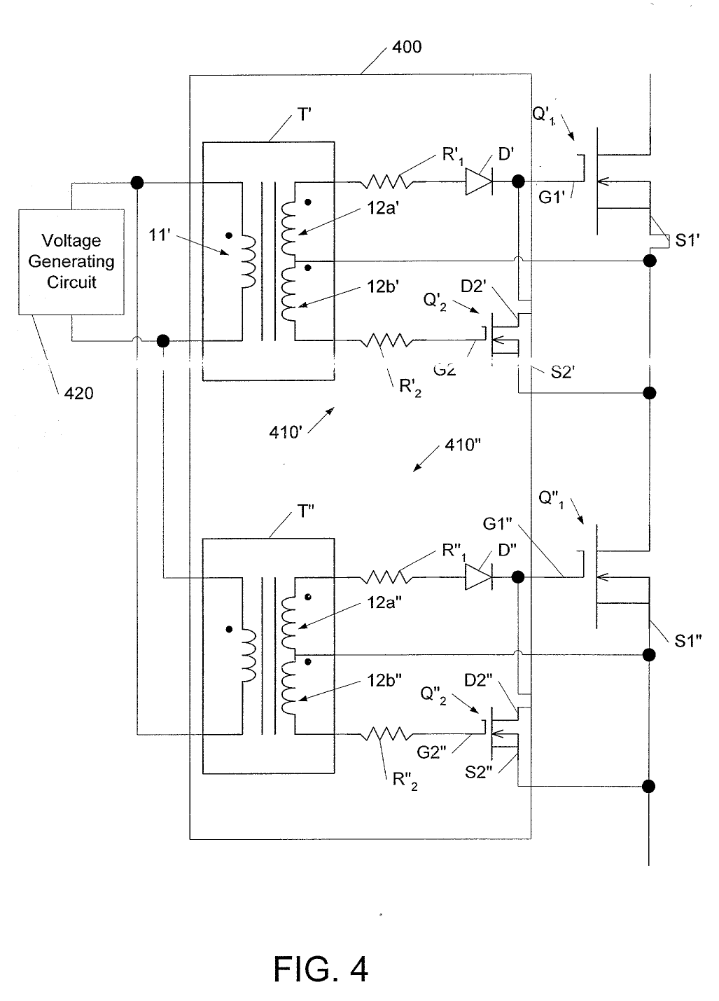

FIG. 4 illustrates a complementary transistor drive circuit 400 for driving a series-connected (totem-pole) combination of transistors Q₁′, Q₁″. The complementary drive circuit 400 includes first and second drive circuits 410′, 410″. The first drive circuit 410′ includes a transformer T′ including a primary winding 11′ magnetically coupled to first and second secondary windings 12a′, 12b′. The first secondary winding 12a′ is coupled to a controlling electrode (e.g., gate) G1′ of a first transistor Q₁′ to be driven via a series combination of a diode D′ and a transistor R₁′. The second secondary winding 12b′ is coupled to a controlling electrode (e.g., gate) G2′ of a transistor Q₂° via a resistor R₂′. The transistor Q₂′ has a first controlled electrode D2′ coupled to the controlling electrode G1′ of the driven transistor Q₁′, and a second controlled electrode (e.g., source/drain) S2′ coupled to a controlled electrode (e.g., source/drain) S1′ of the driven transistor Q₁′. The first drive circuit 410′ is operative to charge and discharge a capacitance (inherent) at the controlling electrode G1′ of the driven transistor Q1′ responsive to a voltage applied to the primary winding 11′ of the transformer T′ by a voltage generating circuit 420.

The second drive circuit 410″ includes a transformer T″ including a primary winding 11″ magnetically coupled to first and second secondary windings 12a″, 12b″. The first secondary winding 12a″ is coupled to a controlling electrode (e.g., gate) G1″ of a second transistor Q₁″ to be driven via a series combination of a diode D″ and a transistor R₁″. The second secondary winding 12b″ of the transformer T″ is coupled to a controlling electrode (e.g., gate) G2″ of a transistor Q₂″ via a resistor R₂″ . The transistor Q₂″ has a first controlled electrode D2″ coupled to the controlling electrode G1″ of the driven transistor Q₁″, and a second controlled electrode (e.g., source/drain) S2″ coupled to a controlled electrode (e.g., source/drain) S2″ of the driven transistor Q₁″. The second drive circuit 410″ is coupled the voltage generating circuit 420 in a polarity arrangement opposite to that of the first drive circuit 410′ , and is operative to charge and discharge a capacitance (inherent) at the controlling electrode G1″ of the driven transistor Q₁″ responsive to a voltage a applied to the primary winding 11″ of the transformer T″ by the voltage generating circuit 420. The second drive circuit 410″ drives the second driven transistor Q₁″ in a manner that is complementary to that in which the first drive circuit drives the first driven transistor Q₁′.

It will be appreciated that the drive circuits in FIGS. 1-4 are offered for illustrative purposes, and that modified and alternative circuit arrangements fall within the scope of the invention. For example, although the complementary drive circuit 400 of FIG. 4 is shown as including separate first and second transformers T′, T″ , similar function could be provided by a unitary magnetic device including windings wound on a common magnetic core and arranged to provide appropriate polarity relationships. In addition, although the circuits 200, 400 of FIGS. 2 and 4 show isolation using magnetic devices (e.g., transformers), isolation of a drive circuit, such as the drive circuit 100 of FIG. 1, may be achieved using other types of isolation devices, such as optical coupling circuits. It will be further appreciated that, although the transistor drive circuits 200, 400 of FIGS. 2 and 4 charge and discharge capacitances directly connected to the controlling electrodes of the transistors that are driven by these circuits, alternative circuit configurations that utilize capacitances that are indirectly coupled to the transistors, such as the configuration illustrated in FIG. 6, may be used.

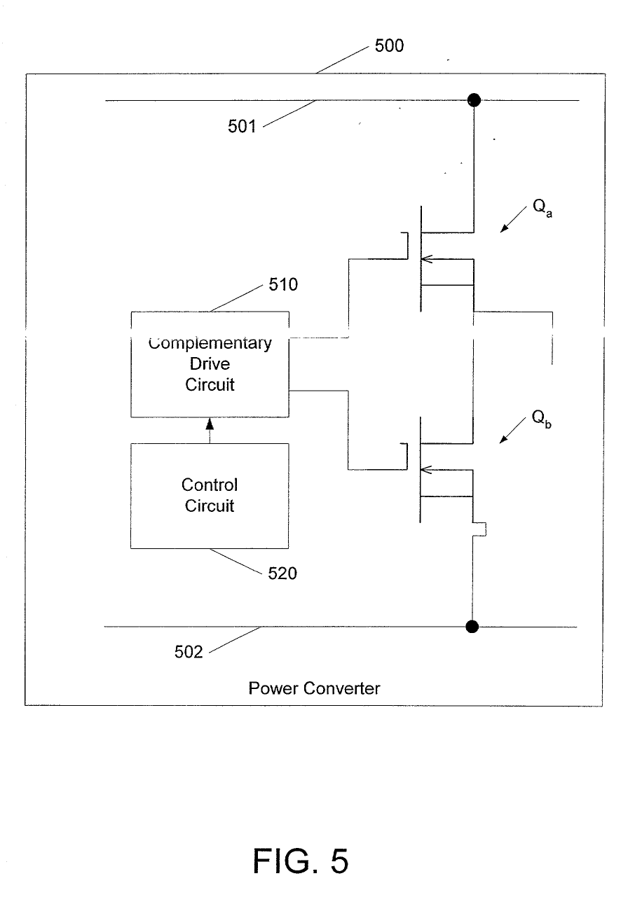

It will be further appreciated that the transistor drive circuits illustrated in FIGS. 1-4 may be used in a variety of applications. For example, as shown in FIG. 5, a complementary drive circuit 510 according to embodiments of the invention may be used in a power conversion apparatus 500, such as a DC power supply, an uninterruptible power supply (UPS), a DC/DC converter, a motor driver, or the like. Here, the complementary drive circuit 510 is shown coupled to a totem-pole configuration of first and second transistors Qₐ, Q_{b} coupled between first and second busses 501, 502, a transistor arrangement that may be used, for example, in a controlled rectifier or inverter circuit. As shown, the complementary drive circuit 510 is controlled by a control circuit 520, which may comprise, for example, a general-purpose microprocessor or microcontroller circuit, or a special-purpose analog and/or digital control circuit.

In the drawings and foregoing description thereof, there have been disclosed typical embodiments of the invention. Terms employed in the description are used in a generic and descriptive sense and not for purposes of limitation, the scope of the invention being set forth in the following claims.

That which is claimed is:

1. A drive circuit for driving a transistor, the drive circuit comprising:
a unidirectional current conducting circuit coupled to a first node and to a controlling electrode of the transistor, the unidirectional current conducting circuit operative to charge a capacitance coupled to the controlling electrode of the transistor responsive to a voltage at the first node; and
a discharge circuit coupled to a second node and operative to control a discharge path from the capacitance responsive to a voltage at the second node.

2. A drive circuit according to claim 1, wherein the capacitance comprises an inherent capacitance of the transistor.

3. A drive circuit according to claim 1, further comprising the capacitance.

4. A drive circuit according to claim 3, further comprising a driver that couples the capacitance to the controlling electrode of the transistor.

5. A drive circuit according to claim 4, further comprising a bias circuit that biases the drive circuit responsive to the voltage at the first node.

6. A drive circuit according to claim 1, wherein the capacitance is directly connected to the controlling electrode of the transistor.

7. A drive circuit according to claim 1:
wherein the unidirectional current conducting circuit is operative to conduct current to the capacitance when the first node is at a first voltage, and wherein the unidirectional current conducting circuit is operative to block current flow from the capacitance when the second node is at a second voltage; and
wherein the discharge circuit is operative to permit current flow through a discharge path when the second node is at a third voltage, and wherein the discharge circuit is operative to block current flow through the discharge path when the second node is at a fourth voltage.

8. A drive circuit according to claim 1:
wherein the unidirectional current conducting circuit is operative to conduct current to the capacitance when the first and second nodes are in a first polarity relationship;
wherein the discharge circuit is operative to block current flow through a discharge path when the first and second nodes are in the first polarity relationship;
wherein the unidirectional current conducting circuit is operative to block current flow from the capacitance when the first and second nodes are at substantially the same voltage;
wherein the discharge circuit is operative to block current flow through the discharge path when the first and second nodes are at substantially the same voltage; and
wherein the discharge circuit is operative to permit current flow through the discharge path when the first and second nodes are in a second polarity relationship opposite the first polarity relationship.

9. A drive circuit according to claim 1, wherein the unidirectional current conducting circuit comprises a diode coupled between the first node and the capacitance.

10. A drive circuit according to claim 1, wherein the transistor comprises a first transistor, and wherein the discharge circuit comprises a second transistor including a controlling electrode coupled to the second node, and a controlled electrode coupled to the capacitance.

11. A drive circuit according to claim 10, wherein the second transistor farther comprises a second controlled electrode coupled to a controlled electrode of the first transistor.

12. A drive circuit according to claim 10, wherein the second transistor comprises a field effect transistor.

13. A drive circuit according to claim 1, further comprising an isolation circuit coupled to the unidirectional current conducting circuit and to the discharge circuit at the first and second nodes, respectively.

14. A drive circuit according to claim 13, wherein the isolation circuit comprises a first winding magnetically coupled to respective ones of second and third windings, wherein the second winding is coupled to the unidirectional current conducting circuit at the first node, and wherein the third winding is coupled to the discharge circuit at the second node.

15. A drive circuit according to claim 1:
wherein the transistor comprises a first transistor;
wherein the unidirectional current conducting circuit comprises a diode coupled between the first node and the capacitance; and
wherein the discharge circuit comprises a second transistor having a controlling electrode coupled to the second node and a controlled electrode coupled to the capacitance.

16. A drive circuit according to claim 15, wherein the unidirectional current conducting circuit comprises a resistor coupled in series with the diode.

17. A drive circuit according to claim 15, wherein the discharge circuit comprises a resistor coupled between the second node and the controlling electrode of the second transistor.

18. A drive circuit for driving a first transistor, the drive circuit comprising:
a diode coupled between a first node and a capacitance coupled to a controlling electrode of the first transistor; and
a second transistor having a controlling electrode coupled to a second node and a controlled electrode coupled to the capacitance.

19. A drive circuit according to claim 18, wherein the capacitance comprises an inherent capacitance of the first transistor.

20. A drive circuit according to claim 18, comprising the capacitance.

21. A drive circuit according to claim 20, further comprising a driver that couples the capacitance to the controlling electrode of the first transistor.

22. A drive circuit according to claim 21, further comprising a bias circuit that biases the driver responsive to the voltage at the first node.

23. A drive circuit according to claim 18, wherein the capacitance is directly connected to the controlling electrode of the first transistor.

24. A drive circuit according to claim 18, further comprising an isolation circuit having an input and an output, wherein the output is coupled to the first and second nodes and wherein the isolation circuit is operative to generate respective first and second voltages at the first and second nodes responsive to a voltage applied at the input.

25. A drive circuit according to claim 24, wherein the isolation circuit comprises a first winding magnetically coupled to respective ones of second and third windings, wherein the second winding is coupled to the first node and the third winding is coupled to the second node.

26. A drive circuit according to claim 24, wherein the isolation circuit comprises a transformer, wherein the first winding comprises a primary winding of the transformer, wherein the second winding comprises a first secondary winding of the transformer, and wherein the third winding comprises a second secondary winding of the transformer.

27. A drive circuit according to claim 18, wherein the second transistor further comprises a second controlled electrode coupled to a controlled electrode of the first transistor.

28. A drive circuit according to claim 18, wherein the second transistor comprises a field effect transistor.

29. A drive circuit according to claim 18, fuirther comprising a resistor coupled in series with the diode between the first node and the capacitance.

30. A drive circuit according to claim 18, fuirther comprising a resistor coupled between the second node and the controlling electrode of the second transistor.

31. A complementary drive circuit for driving first and second transistors, the complementary drive circuit comprising:
a first winding magnetically coupled to respective ones of a second, third, fourth and fifth windings;
a first diode coupled between the second winding and a first capacitance coupled to a controlling electrode of the first transistor;
a third transistor having a controlling electrode coupled to the third winding and a controlled electrode coupled to the first capacitance;
a second diode coupled between the fourth winding and a second capacitance coupled to a controlling electrode of a second transistor; and
a fourth transistor having a controlling electrode coupled to the fifth winding and a controlled electrode coupled to the second capacitance.

32. A complementary drive circuit according to claim 31, wherein the first capacitance comprises an inherent capacitance of the first transistor and wherein the second capacitance comprises an inherent capacitance of the second transistor.

33. A complementary drive circuit according to claim 31, wherein the drive circuit includes the first and second capacitances.

34. A complementary drive circuit according to claim 33, wherein the drive circuit includes a first driver that couples the first capacitance to the controlling electrode of the first transistor and a second driver that couples the second capacitance to the controlling electrode of the second transistor.

35. A complementary drive circuit according to claim 31, wherein the first capacitance is directly connected to the controlling electrode of the first transistor and wherein the second capacitance is directly connected to the controlling electrode of the second transistor.

36. A complementary drive circuit according to claim 31, wherein the first, second, third, fourth and fifth windings are arranged such that a voltage applied across the first winding produces a voltage of a first polarity between an anode of the first diode and the controlling electrode of the third transistor and a voltage of second polarity between an anode of the second diode and the controlling electrode of the fourth transistor.

37. A complementary drive circuit according to claim 36, comprising first and second transformers, wherein the first winding comprises first and second primary windings of the first and second transformers, wherein the second and third windings comprise respective ones of first and second secondary windings of the first transformer, and wherein the fourth and fifth windings comprise respective ones of first and second secondary windings of the second transformer.

38. A complementary drive circuit according to claim 31, further comprising:
a first resistor coupled in series with the first diode;
a second resistor coupled between the third winding and the controlling electrode of the third transistor;
a third resistor coupled in series with the second diode; and
a fourth resistor coupled between the fifth winding and the controlling electrode of the fourth transistor.

39. A power conversion apparatus, comprising:
a transistor; and
a transistor drive circuit including:
a unidirectional current conducting circuit coupled between a first node and a capacitance coupled to a controlling electrode of the transistor, the unidirectional current conducting circuit operative to charge the capacitance responsive to a voltage at the first node; and
a discharge circuit coupled to a second node and operative to control a discharge path from the capacitance responsive to a voltage at the second node.

40. An apparatus according to claim 39, wherein the capacitance comprises an inherent capacitance of the transistor.

41. An apparatus according to claim 39, wherein the transistor drive circuit includes the capacitance.

42. An apparatus according to claim 41, wherein the transistor drive circuit includes a driver that couples the capacitance to the controlling electrode of the transistor.

43. An apparatus according to claim 39, wherein the capacitance is directly connected to the controlling electrode of the transistor.

44. An apparatus according to claim 39, wherein the unidirectional current conducting circuit comprises a diode coupled between the first node and the capacitance.

45. An apparatus according to claim 39, wherein the transistor comprises a first transistor, and wherein the discharge circuit comprises a second transistor including a controlling electrode coupled to the second node, and a controlled electrode coupled to the capacitance.

46. An apparatus according to claim 39, further comprising an isolation circuit coupled to the unidirectional current conducting circuit and to the discharge circuit at the first and second nodes, respectively.

47. An apparatus according to claim 46, wherein the isolation circuit comprises a first winding magnetically coupled to respective ones of second and third windings, wherein the second winding is coupled to the unidirectional current conducting circuit at the first node, and wherein the third winding is coupled to the discharge circuit at the second node.

48. An apparatus according to claim 47, wherein the isolation circuit comprises a transformer, wherein the first winding comprises a primary winding of the transformer, and wherein the second and third windings comprise respective first and second secondary windings of the transformer.

49. An apparatus according to claim 39:
wherein the transistor comprises a first transistor;
wherein the unidirectional current conducting circuit comprises a diode coupled between the first node and the capacitance; and
wherein the discharge circuit comprises a second transistor having a controlling electrode coupled to the second node and a controlled electrode coupled to the capacitance.

50. An apparatus for driving a transistor, the apparatus comprising:
means for unidirectionally conducting current from a first node to a capacitance coupled to a controlling electrode of the transistor responsive to a voltage at the first node to thereby induce a charge on the capacitance and transition the transistor to a first state;
means for maintaining the charge on the capacitance notwithstanding the voltage at the first node to thereby maintain the transistor in the first state; and
means for opening a discharge path from the capacitance responsive to a voltage at a second node the thereby transition the transistor to a second state.

51. A method according to claim 50:
wherein the means for unidirectionally conducting comprises means for conducting current to the capacitance when the first node is at a first voltage;
wherein the means for maintaining comprises means for blocking current flow from the capacitance when the first node is at a second voltage; and wherein the means for opening a discharge path comprises means for permitting current flow through the discharge path when the second node is at a third voltage.

52. A method of driving a transistor, the method comprising:
unidirectionally conducting current from a first node to a capacitance coupled to a controlling electrode of the transistor responsive to a voltage at the first node to thereby induce a charge on the capacitance and transition the transistor to a first state;
maintaining the charge on the capacitance notwithstanding the voltage at the first node to thereby maintain the transistor in the first state; and then opening a discharge path from the capacitance responsive to a voltage at a second node the thereby transition the transistor to a second state.

53. A method according to claim 52, wherein the capacitance comprises an inherent capacitance of the transistor.

54. A method according to claim 52, wherein the capacitance is coupled to the controlling electrode of the transistor via a driver.

55. A method according to claim 52, wherein the capacitance is directly connected to the controlling electrode of the transistor.

56. A method according to claim 52:
wherein the step of unidirectionally conducting comprises conducting current to the capacitance when the first node is at a first voltage;
wherein the step of maintaining comprises blocking current flow from the capacitance when the first node is at a second voltage; and
wherein the step of opening a discharge path comprises permitting current flow through the discharge path when the second node is at a third voltage.

57. A method according to claim 56:
wherein the step of conducting current to the capacitance when the first node is at a first voltage comprises forward biasing a diode coupled between the first node and the capacitance responsive to the first voltage; and
wherein the step of blocking current flow from the capacitance when the first node is at a second voltage comprises reverse biasing the diode responsive to the second voltage; and
wherein the step of permitting current flow through the discharge path when the second node is at a third voltage comprises turning on a transistor having a controlled electrode coupled to the capacitance responsive to the third voltage.

58. A method according to claim 52, further comprising driving the first and second nodes through an isolation circuit.
